(19) United States
(12) Patent Application Publication
(10) Pub. No.: US 2026/0221949 A1
(43) Pub. Date: Jul. 30, 2026

(54) Amplifier Circuit Having a Coil Structure with Mutually Inductively Coupled Coils

(71) Applicant: Infineon Technologies AG, Neubiberg (DE)

(72) Inventor: Christian Musolff, Untersteinach (DE)

(21) Appl. No.: 19/039,121

(22) Filed: Jan. 28, 2025

(51) Int. Cl. H03F 3/195; H03F 1/02

(52) U.S. Cl. CPC H03F 3/195; H03F 1/0288; H03F 2200/451

(57) ABSTRACT

An amplifier circuit includes a first amplifier, a second amplifier, an output connection, and a coil structure. The output connection connects outputs of the first amplifier and second amplifier with a load node. The coil structure includes a first coil and a second coil that are mutually inductively coupled with one another. A first DC voltage feeds the first amplifier through the first coil. A second DC voltage feeds the second amplifier. The output of the first amplifier is connected to the load node through the second coil.

### BACKGROUND

Emerging RF technologies include many high frequency applications with frequencies on the order of 5 GHz (gigahertz), 10 GHz, 20 GHz or more. For example, the extension of cellular communication spectrum towards the X-Band that is expected for the upcoming 6G (sixth generation) standard utilizes frequencies in the range of 6-30 GHz. This will necessitate higher integration of the multiple-input and multiple-output (MIMO) arrays associated with such applications. The design of power amplifier circuits to support RF applications (e.g., multistage amplifier circuits, Doherty Amplifier circuits, etc.) must adhere to multiple performance goals which are often contradictory to each other. These may include space requirements, insertion loss, bandwidth of the fundamental frequency response, bandwidth of the harmonic frequency response, baseband termination impedances, etc. Monolithic integration of a such an amplifier circuit in a monolithic microwave integrated circuit (MMIC) or integrated passive device (IPD), for example, may be especially challenging because of the presence of strong parasitic effects in the passive components on the MMIC. For example, making the bias feed path to an amplifier transistor transparent to RF signals may be difficult to achieve in an MMIC implementation because a sufficiently high inductance may result in a low self-resonance frequency of the bias inductor, such that it imposes significant capacitive loading at the harmonic frequencies to the circuit, which is unfavorable for efficient power amplifier operation. Furthermore, a higher inductance at the fundamental frequency also implies a higher baseband return impedance, which is detrimental to the linearity and linearizability of the power amplifier.

Thus, there is a need for a solution that enables a power amplifier circuit to be monolithically integrated into an MMIC or IPD while meeting the performance requirements of the target application.

### SUMMARY

An amplifier circuit is disclosed. According to an embodiment, the amplifier circuit comprises: a first amplifier; a second amplifier; an output connection that connects outputs of the first amplifier and second amplifier with a load node; and a coil structure comprising a first coil and a second coil that are mutually inductively coupled with one another, wherein a first DC voltage feeds the first amplifier through the first coil, wherein a second DC voltage feeds the second amplifier, and wherein the output of the first amplifier is connected to the load node through the second coil.

According to another embodiment of the amplifier circuit, the amplifier circuit comprises: a Doherty Amplifier circuit comprising a main amplifier device, a peak amplifier device, a first DC voltage feeding the main amplifier device through a first inductance, a second DC voltage feeding the peak amplifier device, and an impedance inverter circuit connected between outputs of the main amplifier device and the peak amplifier device and comprising a second inductance, wherein the Doherty Amplifier circuit is monolithically formed in a semiconductor chip, wherein the first inductance and the second inductance are mutually inductively coupled with one another.

According to another embodiment of an amplifier circuit, the amplifier circuit comprises: a first amplifier, a second amplifier, an output connection, and a coil structure that is monolithically formed in a semiconductor chip, wherein the output connection connects outputs of the first amplifier and second amplifier with a load node; wherein the coil structure comprises a first coil and a second coil that are mutually inductively coupled with one another, wherein a first DC voltage feeds the first amplifier through the first coil, wherein a second DC voltage feeds the second amplifier, and wherein the outputs of the first amplifier and second amplifier are connected through the second coil.

Those skilled in the art will recognize additional features and advantages upon reading the following detailed description, and upon viewing the accompanying drawings.

### BRIEF DESCRIPTION OF THE FIGURES

The elements of the drawings are not necessarily to scale relative to each other. Like reference numerals designate corresponding similar parts. The features of the various illustrated embodiments can be combined unless they exclude each other. Embodiments are depicted in the drawings and are detailed in the description which follows.

FIG. 1 illustrates a circuit schematic of an amplifier circuit, according to an embodiment.

FIG. 2 illustrates a physical implementation of an amplifier circuit, according to an embodiment.

FIGS. 3A-3D illustrate a coil structure of an amplifier circuit, according to embodiments.

### DETAILED DESCRIPTION

Described herein is a multi-device amplifier circuit for amplifying an RF signal. In an embodiment, the amplifier circuit is arranged as a Doherty Amplifier. The amplifier circuit includes a first amplifier and a second amplifier each having a respective input and output. The amplifier circuit further includes a first inductance (e.g., a biasing shunt inductance) through which a DC bias is fed to the first amplifier, and a second inductance that is part of an impedance inverter circuit (e.g., a series inductance) connected between the output of the first amplifier and the output of the second amplifier. An output connection connects the outputs of the first amplifier and second amplifier with a load node, wherein an amplified RF signal is outputted.

According to embodiments of this disclosure, the first inductance and the second inductance of the amplifier circuit are mutually inductively coupled with one another. In one embodiment, the first and second inductances are formed by a coil structure, with a first coil of the coil structure forming the first inductance and a second coil of the coil structure forming the second inductance. The mutual inductive coupling between the first inductance and the second inductance may be realized by forming the first coil and the second coil in an arrangement in which the coils are adjacent to one another, for example laterally adjacent and substantially coplanar with one another.

Forming the amplifier circuit with a first inductance and a second inductance that are mutually inductively coupled with one another as disclosed herein may provide the amplifier circuit with numerous design and performance advantages. For example, such a structure may enable the inductance of the first coil (the first inductance) and the second coil (the second inductance) to be decreased. Such a reduction of the respective inductances may reduce associated parasitic effects, potentially also reducing insertion loss and enhancing bandwidth of the amplifier circuit and thus achieving a desired network response of the amplifier circuit. Moreover, the design disclosed herein may provide spatial layout advantages enabling monolithic integration of the amplifier circuit in a smaller chip (e.g., an MMIC or IPD) and providing a higher integration level in target application while maintaining favorable RF performance in terms of efficiency, bandwidth, and linearizability.

Described next, with reference to the figures, are exemplary embodiments of the amplifier circuit.

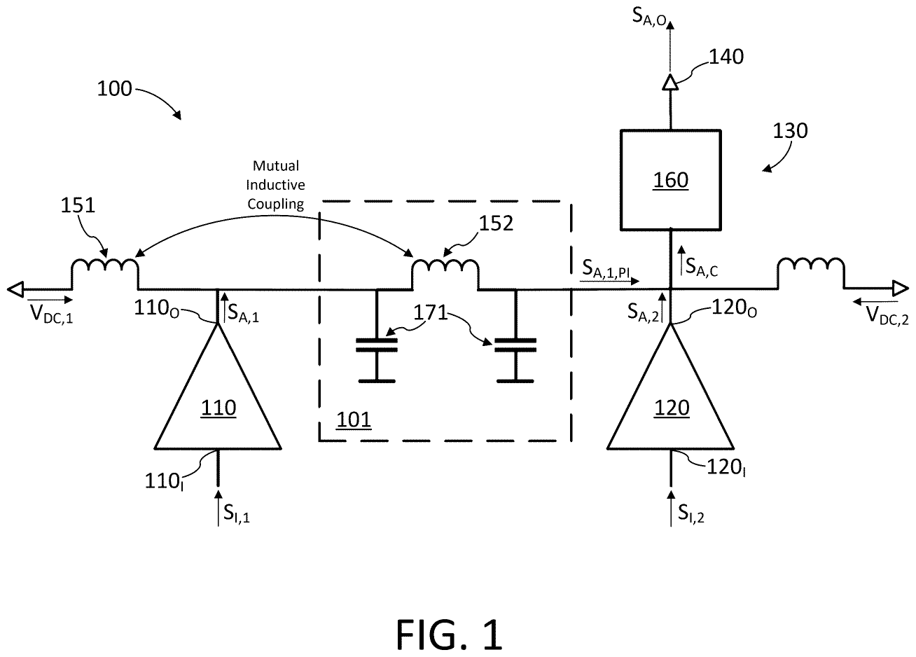

FIG. 1 illustrates a circuit schematic of an amplifier circuit 100, according to an embodiment. The amplifier device 100 is configured to amplify a signal, e.g., an RF signal. Generally speaking, the RF signal can be in the range of 100 MHz (megahertz) to 100 GHz (gigahertz). According to an embodiment, the RF signal is a telecommunications signal, e.g., a carrier signal in the 4G (4th generation), 5G (5th generation), or 6G (6th generation) technology standard for cellular networks. For example, the RF signal may be in any one or more of the following cellular and millimeter frequency bands: 600 MHz; 700 MHz; 800 MHz; 900 MHz; 1.5 GHz; 2.1 GHz; 2.3 GHz; 2.6 GHz; 3.6 GHz; 4.7 GHz; 26 GHz; 28 GHz; 37 GHz; 39 GHz; and 60 GHz. In a particular embodiment, a frequency of the RF signal is between 6.4 GHz and 7.2 GHz.

The amplifier circuit 100 includes a first amplifier 110 and a second amplifier 120. According to an embodiment, the amplifier circuit 100 is a Doherty Amplifier circuit 100, with the first amplifier 110 being a main amplifier device 110 and the second amplifier 120 being a peak amplifier device 120. Hereafter, both the amplifier circuit 100 and the Doherty Amplifier circuit 100 may be referenced as appropriate to the discussion. Likewise, both the first amplifier 110 and the main amplifier device 110 and both the second amplifier 120 and the peak amplifier device 120 may be referenced as appropriate to the discussion. More generally, the embodiments disclosed herein encompass any type of multi-amplifier device.

Each of the first amplifier 110 and the second amplifier 120 includes an input (inputs 110_{I} and 120_{I}, respectively) and an output (outputs 110_{O} and 120_{O}, respectively). The inputs 110_{I} and 120_{I} may be RF input terminals. Likewise, the outputs 110_{O} and 120_{O} may be RF output terminals. An output connection 130 connects the outputs 110_{O} and 120_{O} of the first amplifier 110 and second amplifier 120, respectively, with a load node 140.

During operation of the amplifier circuit 100, a first DC voltage V_{DC,1} feeds the first amplifier 110 (e.g., the output 110_{O} of the first amplifier 110) through a first inductance 151 of the amplifier circuit 110. The first inductance 151 through which the first DC voltage V_{DC,1} is fed may, for example, be a biasing shunt inductance 151. Hereafter, both the first inductance 151 and the biasing shunt inductance 151 may be referenced as appropriate to the discussion. A second DC voltage V_{DC,2} feeds the second amplifier 120 (e.g., the output 120_{O} of the second amplifier 120). Each of the first amplifier 110 and the second amplifier 120 may receive an input signal (S_{I,1} and S_{I,2}, respectively). The input signals S_{I,1} and S_{I,2} may be RF input signals. In the example of the Doherty Amplifier circuit 100, the input signals S_{I,1} and S_{I,2} may be RF signals that are split from a single RF signal (e.g., by a power divider, not shown) prior to reaching the main amplifier device 110 and the peak amplifier device 120, respectively. Likewise, an amplified signal (e.g., an amplified RF signal) may be output from the output 110_{O} of the first amplifier 110 and the output 120_{O} of the second amplifier 120, illustrated here as amplified signals S_{A,1} and S_{A,2}, respectively.

The amplifier circuit 100 further includes an impedance inverter circuit 101 connected between the output 110_{O} of the first amplifier 110 and the output 120_{O} of the second amplifier 120. The impedance inverter circuit 101 includes a second inductance 152 and may include other passive and/or active components (e.g., capacitors 171, as illustrated in FIG. 1). The second inductance 152 may, for example, be a series inductance 152. Hereafter, both the second inductance 152 and the series inductance 152 may be referenced as appropriate to the discussion. The amplified signal S_{A,1} from the output 110_{O} of the first amplifier 110 may pass through the impedance inverter circuit 101 and result in an amplified phase inverted signal S_{A,1,PI}. The amplified phase inverted signal S_{A,1,PI} may be combined with or, in the example of the Doherty Amplifier circuit 100, recombined with the amplified signal S_{A,2} from the output 120_{O} of the second amplifier 120 to form a combined amplifier signal S_{A,C}. The combined amplified S_{A,C} may then pass through the output connection 130 and be output (e.g., to a load) as an amplified output signal S_{A,O} from the load node 140. The amplified output S_{A,O} may be an amplified signal (e.g., an amplified RF signal) that represents the input signals S_{I,1} and S_{I,2}. In the amplifier circuit 100 of FIG. 1, the output connection 130 includes an output circuit 160 (e.g., a passive LC circuit configured for impedance matching).

According to an embodiment, the first inductance 151 and the second inductance 152 of the amplifier circuit 100 are mutually inductively coupled with one another. That is, the first inductance 151 and the second inductance 152 are spatially arranged relative to one another such that a current flowing through the first inductance 151 generates a magnetic field that consequently induces a current in the second inductance 152. A coupling coefficient between the first inductance 151 and the second inductance 152 may be greater than 0.1, in some examples up to 0.5. As will be discussed with reference to subsequent figures, this mutual inductive coupling may be enabled by the physical implementation of the first inductance 151 and the second inductance 152.

Forming the first inductance 151 and the second inductance 152 such that they are mutually inductively coupled with one another as disclosed herein may enable the first inductance 151 and/or the second inductance 152 (e.g., the biasing shunt inductance 151 and/or the series inductance 152, respectively, of the Doherty Amplifier circuit 100) to be smaller when compared to similar amplifier circuits in which the first/biasing shunt inductance 151 and the second/series inductance 152 are not mutually inductively coupled with one another. Reducing the first/biasing shunt inductance 151 may lower the impedance of the baseband of the amplifier circuit 100, potentially improving wideband linearity and linearizability of the amplifier circuit 100 (e.g., the Doherty Amplifier circuit 100). A smaller first/biasing shunt inductance 151 may also provide higher self-resonance, potentially enabling less capacitive loading of the first amplifier 110 (e.g., the main amplifier device 110) at the second harmonic and/or providing more efficient waveform shaping within inverse Class F design space of the amplifier circuit 100 (e.g., the Doherty Amplifier circuit 100). Furthermore, reducing the first/biasing shunt inductance 151 and/or the second/series inductance 152 may increase the effective inductance per unit length, potentially reducing insertion loss (RF and DC losses) of the amplifier circuit 100 (e.g., the Doherty Amplifier circuit 100).

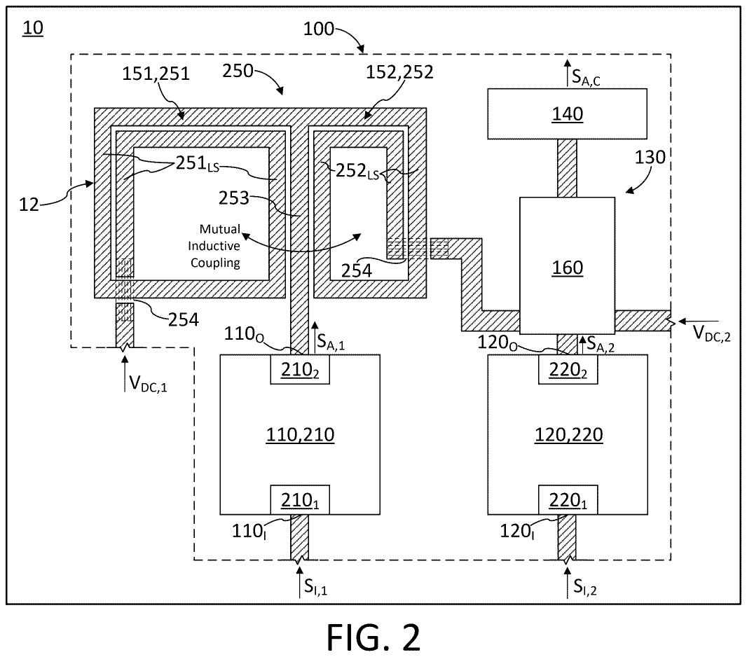

FIG. 2 illustrates a physical implementation of the amplifier circuit 100, according to an embodiment. In this example, the amplifier circuit 100 (e.g., the Doherty Amplifier circuit 100) is monolithically formed in a semiconductor chip 10. More specifically, the first amplifier 110 (e.g., the main amplifier 110), the second amplifier 120 (e.g., the peak amplifier 120), the output connection 130, the first inductance 151, the second inductance 152, etc., are monolithically formed in the semiconductor chip 10. Generally speaking, the amplifier circuit 100 can be monolithically formed in the semiconductor chip 10 using standard wafer fabrication processes.

In the example illustrated in FIG. 2, the first amplifier 110 (e.g., the main amplifier device 110 of the Doherty Amplifier circuit 100) is a first power transistor 210. Likewise, the second amplifier 120 (e.g., the peak amplifier 120 of the Doherty Amplifier circuit 100) is a second power transistor 220. Although the first power transistor 210 and the second power transistor 220 are each illustrated in FIG. 2 as a single transistor, the first power transistor 210 and/or the second power transistor 220 may include more than one individual transistor (e.g., a multistage transistor device that includes a drive stage transistor and an output stage transistor). Separately or in combination, the first power transistor 210 and/or the second power transistor 220 may be implemented by multiple transistor devices and/or multi-cell transistor devices.

Generally speaking, the first power transistor 210 and the second power transistor 220 can be fabricated in any device technology. For example, the first power transistor 210 and/or the second power transistor 220 may include semiconductor materials such as elementary semiconductor materials such as silicon (Si) or germanium (Ge), group IV compound semiconductor materials such as silicon carbide (SiC) or silicon germanium (SiGe), binary, ternary or quaternary III-V semiconductor materials such as gallium nitride (GaN), gallium arsenide (GaAs), gallium phosphide (GaP), indium phosphide (InP), indium gallium phosphide (InGaPa), aluminum gallium nitride (AlGaN), aluminum indium nitride (AlInN), indium gallium nitride (InGaN), aluminum gallium indium nitride (AlGaInN) or indium gallium arsenide phosphide (InGaAsP), etc.

According to an embodiment, the first power transistor 210 and the second power transistor 220 are each configured as RF power transistors. Examples of these RF power transistors include Bipolar Junction Transistors (BJT), Metal-Oxide-Semiconductor Field-Effect Transistors (MOSFET), Laterally Diffused Metal-Oxide-Semiconductor (LDMOS) transistors, Gallium Arsenide (GaAs) transistors, Gallium Nitride (GaN) transistors, High Electron Mobility Transistors (HEMTs), Silicon Carbide (SiC) transistors, etc. In one embodiment, the first and second power transistors 210 and 220 are each configured as GaN HEMT devices.

Each of the first power transistor 210 and the second power transistor 220 includes a first terminal (first terminals 210₁ and 220₁, respectively) and a second terminal (second terminals 210₂ and 220₂, respectively). The first terminals 210₁ and 220₁ correspond to the inputs 110_{I} and 120_{I} of the first amplifier 110 and the second amplifier 120 respectively. The first terminals 210₁ and 220₁ may each correspond to a gate, base, etc. of the first power transistor 210 and the second power transistor 220, respectively. The second terminals 210₂ and 220₂ correspond to the outputs 110_{O} and 120_{O} of the first amplifier 110 and the second amplifier 120, respectively. The second terminals 210₂ and 220₂ may each correspond to a drain, collector, etc., of the first power transistor 210 and the second power transistor 220, respectively. In examples in which the first power transistor 210 and/or the second power transistor 220 includes more than one individual transistor, the respective first terminal 210₁ and/or 220₁ may be associated with a first individual transistor and the respective second terminal 210₂ and/or 220₂ may be associated with a second, different individual transistor.

During operation of the amplifier circuit 100 illustrated in FIG. 2, the first DC voltage V_{DC,1} feeds the second terminal 210₂ (e.g., the drain, the collector) of the first power transistor 210 and the second DC voltage V_{DC,2} feeds the second terminal 220₂ (e.g., the drain, the collector) of the second power transistor 220. At the chip level, the first and second DC voltages V_{DC,1} and V_{DC,2} can be independently delivered via separate pins/terminals. Alternatively, a single voltage may be externally provided to the chip and separate DC voltages may be created on chip with dedicated power circuitry. The input signal S_{I,1} feeds the first terminal 210₁ (e.g., the gate, the base) of the first power transistor 210 and the input signal S_{I,2} feeds the first terminal 220₁ (e.g., the gate, the base) of the second power transistor 220. A third terminal of each of the first power transistor 210 and the second power transistor 220 (not illustrated in FIG. 2), for example a source or emitter, may be connected to a ground or other voltage source.

According to an embodiment, the first inductance 151 and the second inductance 152 of the amplifier circuit 100 are each formed by a coil structure 250. In the example illustrated in FIG. 2, the coil structure 250 is formed in a metallization layer 12 of the semiconductor chip 10. For example, the coil structure 250 may be formed in a first-level metallization of the semiconductor chip 10 that is separated from the semiconductor body by an interlayer dielectric comprising, e.g., SiO₂ (silicon dioxide), SiN (silicon nitride), etc. The coil structure 250 may be formed in a first-level metallization of the semiconductor chip 10 from patterned tracks comprising gold, copper, aluminum, nickel, and alloys thereof. These be patterned tracks may have a thickness on the order of 1 μm, 5 μm, 10 μm or more and a width on the order of 5 μm, 20 μm, 50 μm or more.

The coil structure 250 includes a first coil 251 and a second coil 252, with the first coil 251 forming the first inductance 151 and the second coil 252 forming the second inductance 152. During operation of the amplifier circuit 100, the first DC voltage V_{DC,1} feeds first amplifier 110 (e.g., the first power transistor 210) through the first coil 251. The output 110_{O} of the first amplifier 110 (e.g., the second terminal 210₂ of the first power transistor 210) is connected to the load node 140 of the amplifier circuit 110 through the second coil 252. As with the respective inductances 151 and 152 that each of the first coil 251 and the second coil 252 form, the first coil 251 and the second coil 252 are mutually inductively coupled with one another. A coupling coefficient between the first coil 251 and the second coil 252 may be greater than 0.1, in some examples up to 0.5.

In the example of the coil structure 250 of FIG. 2, the first coil 251 and the second coil 252 are laterally adjacent and substantially coplanar with one another. The first and second coils 251 and 252 each include linear spans 251_{LS} and 252_{LS}, respectively. The linear spans 251_{LS} of the first coil 251 run substantially parallel to the linear spans 252_{LS} of the second coil 252. The first and second coils 251 and 252 may have an asymmetric geometry, for example asymmetric width, height, shape, etc. In this example, the first and second coils 251 and 252 have a rectangular shape, although other shapes are contemplated.

In addition to the first coil 251 and the second coil 252, the coil structure 250 further includes a central connector 253 and outer connectors 254. The central connector 253 is arranged between the linear spans 251_{LS} and 252_{LS} of the first and second coils 251 and 252. A first end of the central connector 253 connects with each of the first and second coils 251 and 252. A second, opposite end of the central connector 253 connects with the first power transistor 210 (e.g., the second terminal 210₂ of the first power transistor 210). The outer connectors 254 may be implemented using vias, metallic sublayers, etc. to route the lines under or over the respective coil structure, and thereby connect the coil structure 250 with other features, components, etc. (e.g., a bias feed that provides the first DC voltage V_{DC,1}, the output 120_{O} of the second amplifier 120, etc.)

Implementing the first/biasing shunt inductance 151 and the second/series inductance 152 of the amplifier circuit 100 as adjacent coils 251 and 252, respectively, may provide flexibility in the layout of the amplifier circuit 100, for example by enabling the amplifier circuit 100 to be smaller when compared with other designs. In some examples, this layout flexibility may enable the amplifier circuit 100 to be integrated into a smaller chip design (e.g., an MMIC or IPD) and may reduce the manufacturing cost of the associated amplifier device. This implementation of the first inductance 151/first coil 251 and second inductance 152/second coil 252 illustrated in FIG. 2 is just one example, however, and other similarly advantageous coil/inductor implementations are contemplated (e.g., octagonal planar inductors, 3D integrated inductors).

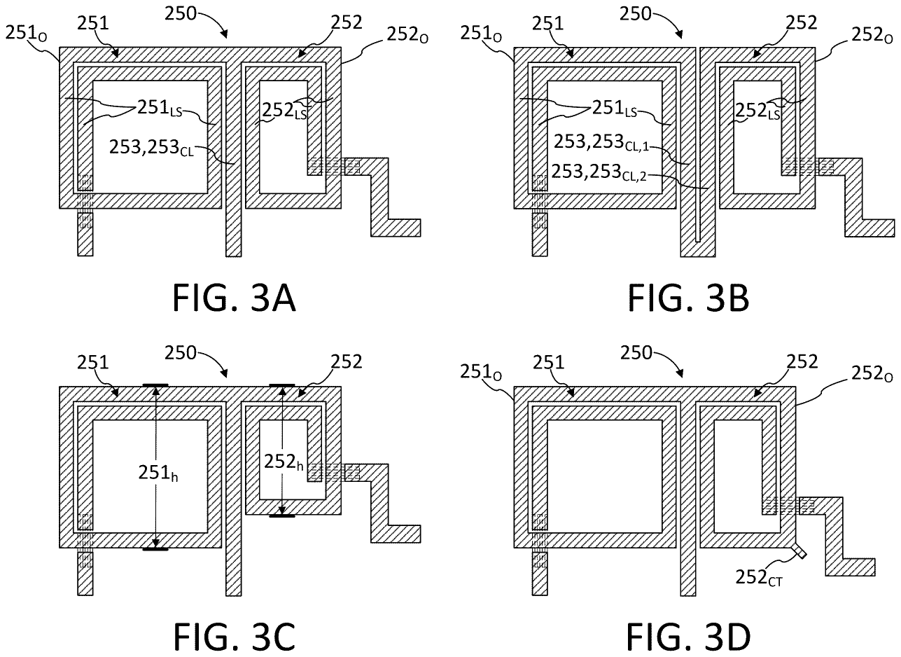

FIGS. 3A-3D illustrate the coil structure 250 of the amplifier circuit 100, according to embodiments.

FIG. 3A illustrates the embodiment of the coil structure 250 that is included in the amplifier circuit 100 of FIG. 2. Specifically, the coil structure 250 of FIG. 3A includes the central connector 253 that connects with each of the first and second coils 251 and 252 and is arranged between the linear spans 251_{LS} and 252_{LS} of the first and second coils 251 and 252. In this example, the central connector 253 includes a single center leg 253_{CL}. An outer winding 251_{O} of the first coil 251 and an outer winding 252_{O} of the second coil 252 each merge with the single center leg 253_{CL} of the central connector 253. Forming the coil structure 250 with the single center leg 253_{CL} shared by the first coil 251 and the second coil 252 may minimize the size of the coil structure 250 and maximize the mutually inductive coupling between the first coil 251 and the second coil 252.

FIG. 3B illustrates an embodiment of the coil structure 250 in which the central connector 253 includes a first center leg 253_{CL,1} and a second center leg 253_{CL,2}. The outer winding 251_{O} of the first coil 251 merges with the first center leg 253_{CL,1}. The outer winding 252_{O} of the second coil 252 merges with the second center leg 253_{CL,2}. In this example, the first center leg 253_{CL,1} and the second center leg 253_{CL,2} merge with one another.

FIG. 3C illustrates one embodiment of the coil structure 250 in which the first coil 251 and the second coil 252 have an asymmetric geometry. Specifically, a height 251ₕ of the first coil 251 is greater than a height 252ₕ of the second coil 252. Structuring the first coil 251 and the second coil 252 in this way may enable a desired network response of the associated amplifier device to be achieved.

FIG. 3D illustrates an embodiment of the coil structure 250 in which the second coil 252 includes a center tap 252_{CT} that protrudes out from the outer winding 252_{O} of the second coil 252. The center tap 252_{CT} may be used for frequency response/bandwidth enhancement techniques such as capacitive loading.

Although the present disclosure is not so limited, the following numbered examples demonstrate one or more aspects of the disclosure.

Example 1. An amplifier circuit, comprising: a first amplifier; a second amplifier; an output connection that connects outputs of the first amplifier and second amplifier with a load node; and a coil structure comprising a first coil and a second coil that are mutually inductively coupled with one another, wherein a first DC voltage feeds the first amplifier through the first coil, wherein a second DC voltage feeds the second amplifier, and wherein the output of the first amplifier is connected to the load node through the second coil.

Example 2. The amplifier circuit of example 1, wherein a coupling coefficient between the first coil and the second coil is less than 0.5.

Example 3. The amplifier circuit of example 2, wherein the coupling coefficient between the first coil and the second coil is greater than 0.1.

Example 4. The amplifier circuit of any of examples 1 through 3, wherein the first and second coils each comprise linear spans, and wherein the linear spans of the first coil run substantially parallel to the linear spans of the second coil.

Example 5. The amplifier circuit of example 4, wherein the first and second coils have a rectangular shape.

Example 6. The amplifier circuit of example 4 or 5, wherein the coil structure comprises a central connector that connects with each of the first and second coils, and wherein the central connector is arranged between the linear spans of the first and second coils.

Example 7. The amplifier circuit of example 6, wherein the central connector comprises a first center leg and a second center leg, wherein an outer winding of the first coil merges with the first center leg, and wherein an outer winding of the second coil merges with the second center leg.

Example 8. The amplifier circuit of example 6, wherein the central connector comprises a single center leg, wherein an outer winding of the first coil merges with the single center leg, and wherein an outer winding of the second coil merges with the single center leg.

Example 9. The amplifier circuit of any of examples 1 through 8, wherein the first and second coils have an asymmetric geometry.

Example 10. The amplifier circuit of example 9, wherein a height of the first coil is greater than a height of the second coil.

Example 11. The amplifier circuit of any of examples 1 through 10, wherein the coil structure further comprises a center tap of the second coil, and wherein the center tap of the second coil protrudes out from an outer winding of the second coil.

Example 12. The amplifier circuit of any of examples 1 through 11, wherein the amplifier circuit is monolithically formed in a semiconductor chip, and wherein the coil structure is formed in a metallization layer of the semiconductor chip.

Example 13. The amplifier circuit of example 12, wherein the first amplifier is a first power transistor and the second amplifier is a second power transistor, wherein the first DC voltage feeds a drain terminal of the first power transistor, and wherein the second DC voltage feeds a drain terminal of the second power transistor.

Example 14. The amplifier circuit of example 13, wherein the first and second power transistors are each configured as GaN HEMT devices.

Example 15. An amplifier circuit, comprising: a Doherty Amplifier circuit comprising a main amplifier device, a peak amplifier device, a first DC voltage feeding the main amplifier device through a first inductance, a second DC voltage feeding the peak amplifier device, and an impedance inverter circuit connected between outputs of the main amplifier device and the peak amplifier device and comprising a second inductance, wherein the Doherty Amplifier circuit is monolithically formed in a semiconductor chip, wherein the first inductance and the second inductance are mutually inductively coupled with one another.

Example 16. The amplifier circuit of example 15, wherein the first inductance and the second inductance are each formed by a coil structure that is formed in a metallization layer of the semiconductor chip.

Example 17. The amplifier circuit of example 16, wherein the coil structure comprises a first coil and a second coil that are laterally adjacent and substantially coplanar with one another, wherein the first coil forms the first inductance, and wherein the second coil forms the second inductance.

Example 18. The amplifier circuit of any of examples 15 through 17, wherein the main amplifier device is a first power transistor and the peak amplifier device is a second power transistor, wherein the first DC voltage feeds a drain terminal of the first power transistor, and wherein the second DC voltage feeds a drain terminal of the second power transistor.

Example 19. The amplifier circuit of example 18, wherein the first and second power transistors are each configured as GaN HEMT devices.

Example 20. An amplifier circuit, comprising: a first amplifier, a second amplifier, an output connection, and a coil structure that is monolithically formed in a semiconductor chip, wherein the output connection connects outputs of the first amplifier and second amplifier with a load node; wherein the coil structure comprises a first coil and a second coil that are mutually inductively coupled with one another, wherein a first DC voltage feeds the first amplifier through the first coil, wherein a second DC voltage feeds the second amplifier, and wherein the outputs of the first amplifier and second amplifier are connected through the second coil.

As used herein, the terms “connects,” “connected,” and the like indicate electrical connection either directly or through one or more intervening passive components (e.g., capacitors, resistors, inductors, etc.) and/or passive circuits (e.g., LC (resonant) circuits).

Terms such as “first”, “second”, and the like, are used to describe various elements, regions, sections, etc. and are also not intended to be limiting. Like terms refer to like elements throughout the description.

As used herein, the terms “having”, “containing”, “including”, “comprising” and the like are open ended terms that indicate the presence of stated elements or features, but do not preclude additional elements or features. The articles “a”, “an” and “the” are intended to include the plural as well as the singular, unless the context clearly indicates otherwise.

The expression “and/or” should be interpreted to include all possible conjunctive and disjunctive combinations, unless expressly noted otherwise. For example, the expression “A and/or B” should be interpreted to mean A but not B, B but not A, or both A and B. The expression “at least one of” should be interpreted in the same manner as “and/or”, unless expressly noted otherwise. For example, the expression “at least one of A and B” should be interpreted to mean A but not B, B but not A, or both A and B.

It is to be understood that the features of the various embodiments described herein can be combined with each other, unless specifically noted otherwise.

Although specific embodiments have been illustrated and described herein, it will be appreciated by those of ordinary skill in the art that a variety of alternate and/or equivalent implementations can be substituted for the specific embodiments shown and described without departing from the scope of the present invention. This application is intended to cover any adaptations or variations of the specific embodiments discussed herein. Therefore, it is intended that this invention be limited only by the claims and the equivalents thereof.

What is claimed is:

1. An amplifier circuit, comprising:
a first amplifier;
a second amplifier;
an output connection that connects outputs of the first amplifier and second amplifier with a load node; and
a coil structure comprising a first coil and a second coil that are mutually inductively coupled with one another,
wherein a first DC voltage feeds the first amplifier through the first coil,
wherein a second DC voltage feeds the second amplifier, and
wherein the output of the first amplifier is connected to the load node through the second coil.

2. The amplifier circuit of claim 1, wherein a coupling coefficient between the first coil and the second coil is less than 0.5.

3. The amplifier circuit of claim 2, wherein the coupling coefficient between the first coil and the second coil is greater than 0.1.

4. The amplifier circuit of claim 1,
wherein the first and second coils each comprise linear spans, and
wherein the linear spans of the first coil run substantially parallel to the linear spans of the second coil.

5. The amplifier circuit of claim 4, wherein the first and second coils have a rectangular shape.

6. The amplifier circuit of claim 4, wherein the coil structure comprises a central connector that connects with each of the first and second coils, and wherein the central connector is arranged between the linear spans of the first and second coils.

7. The amplifier circuit of claim 6, wherein the central connector comprises a first center leg and a second center leg, wherein an outer winding of the first coil merges with the first center leg, and wherein an outer winding of the second coil merges with the second center leg.

8. The amplifier circuit of claim 6, wherein the central connector comprises a single center leg, wherein an outer winding of the first coil merges with the single center leg, and wherein an outer winding of the second coil merges with the single center leg.

9. The amplifier circuit of claim 1, wherein the first and second coils have an asymmetric geometry.

10. The amplifier circuit of claim 9, wherein a height of the first coil is greater than a height of the second coil.

11. The amplifier circuit of claim 1, wherein the coil structure further comprises a center tap of the second coil, and wherein the center tap of the second coil protrudes out from an outer winding of the second coil.

12. The amplifier circuit of claim 1, wherein the amplifier circuit is monolithically formed in a semiconductor chip, and wherein the coil structure is formed in a metallization layer of the semiconductor chip.

13. The amplifier circuit of claim 12, wherein the first amplifier is a first power transistor and the second amplifier is a second power transistor, wherein the first DC voltage feeds a drain terminal of the first power transistor, and wherein the second DC voltage feeds a drain terminal of the second power transistor.

14. The amplifier circuit of claim 13, wherein the first and second power transistors are each configured as GaN HEMT devices.

15. An amplifier circuit, comprising:
A Doherty Amplifier circuit comprising a main amplifier device, a peak amplifier device, a first DC voltage feeding the main amplifier device through a first inductance, a second DC voltage feeding the peak amplifier device, and an impedance inverter circuit connected between outputs of the main amplifier device and the peak amplifier device and comprising a second inductance,
wherein the Doherty Amplifier circuit is monolithically formed in a semiconductor chip,
wherein the first inductance and the second inductance are mutually inductively coupled with one another.

16. The amplifier circuit of claim 15, wherein the first inductance and the second inductance are each formed by a coil structure that is formed in a metallization layer of the semiconductor chip.

17. The amplifier circuit of claim 16, wherein the coil structure comprises a first coil and a second coil that are laterally adjacent and substantially coplanar with one another, wherein the first coil forms the first inductance, and wherein the second coil forms the second inductance.

18. The amplifier circuit of claim 15, wherein the main amplifier device is a first power transistor and the peak amplifier device is a second power transistor, wherein the first DC voltage feeds a drain terminal of the first power transistor, and wherein the second DC voltage feeds a drain terminal of the second power transistor.

19. The amplifier circuit of claim 18, wherein the first and second power transistors are each configured as GaN HEMT devices.

20. An amplifier circuit, comprising:
a first amplifier, a second amplifier, an output connection, and a coil structure that is monolithically formed in a semiconductor chip,
wherein the output connection connects outputs of the first amplifier and second amplifier with a load node;
wherein the coil structure comprises a first coil and a second coil that are mutually inductively coupled with one another,
wherein a first DC voltage feeds the first amplifier through the first coil,
wherein a second DC voltage feeds the second amplifier, and
wherein the outputs of the first amplifier and second amplifier are connected through the second coil.
